(19) United States
(12) Patent Application Publication
(10) Pub. No.: US 2012/0168723 A1
(43) Pub. Date: Jul. 5, 2012

(54) ELECTRONIC DEVICES INCLUDING GRAPHENE AND METHODS OF FORMING THE SAME

(75) Inventor: Kunsik PARK, Daejeon (KR)

(73) Assignee: Electronics and Telecommunications Research Institute, Daejeon (KR)

(21) Appl. No.: 13/335,709

(22) Filed: Dec. 22, 2011

(30) Foreign Application Priority Data
Dec. 29, 2010 (KR) 10-2010-0138022
Nov. 8, 2011 (KR) 10-2011-0115828

(51) Int. Cl. H01L 29/16; H01L 21/20; B82Y 40/00

(52) U.S. Cl. 257/29; 438/478; 977/842; 257/E21.09; 257/E29.082

(57) ABSTRACT

Methods of forming a graphene layer are provided. The method includes sequentially forming a seed layer and a protection layer on a substrate, patterning the protection layer and the seed layer to form a protection pattern and a seed pattern having a first length in a first direction and a second length in a second direction perpendicular to the first direction, and forming a graphene material on at least one of both sidewalls of the seed pattern. The second length is greater than the first length. Related devices are also provided.

### CROSS-REFERENCE TO RELATED APPLICATIONS

This U.S. non-provisional patent application claims priority under 35 U.S.C. §119 to Korean Provisional Patent Application No. 10-2010-0138022 and Korean Regular Patent Application No. 10-2011-0115828, filed on Dec. 29, 2010 and Nov. 8, 2011, respectively, the disclosures of which are hereby incorporated by reference in their entireties.

### BACKGROUND

1. Technical Field

The present disclosure herein relates to electronic devices including a graphene material, and methods of forming electronic devices including a graphene material.

2. Description of Related Art

A graphene material is a single layer (corresponding to a two dimensional plate having a thickness of about 4 angstroms) composed of benzene rings that are made of carbon atoms. The graphene material may constitute a multi-walled carbon nanotube (MWCNT) or a graphite material. The graphene material may exhibit high electron mobility of about 200,000 cm²/Vs, excellent optical transparency of about 80% or the higher, metal-like electrical conductivity and excellent thermal conductivity. Thus, the graphene material can be widely used in semiconductor industry, energy industry, display industry or the like.

The graphene material may be formed using a mechanical exfoliation process, a chemical exfoliation process, a chemical vapor deposition (CVD) process, an epitaxial growth process or an organic synthesis process.

However, in the mechanical or chemical exfoliation process, it may be difficult to accurately control the process for forming the graphene material. The chemical exfoliation process for forming the graphene material may be performed by separating a catalyst layer and a graphene material from a first substrate, removing the catalyst layer, and transferring the graphene material onto a second substrate used as a real device substrate. The epitaxial growth process for forming the graphene material may necessitate a high priced substrate such as a silicon carbide (SiC) substrate and a high temperature process performed at about 1600° C.

### SUMMARY

Exemplary embodiments are directed to methods of forming a graphene material with simplified processes, electronic devices employing the graphene material, and methods of forming the electronic device including the graphene material.

In an exemplary embodiment, a method of forming a graphene device includes sequentially forming a seed layer and a protection layer on a substrate, patterning the protection layer and the seed layer to form a protection pattern and a seed pattern having a first length in a first direction and a second length in a second direction perpendicular to the first direction, and forming a graphene layer on at least one of both sidewalls of the seed pattern. The second length being greater than the first length.

Forming the graphene layer may include forming a pair of graphene patterns on respective ones of both sidewalls of the seed pattern. The pair of graphene patterns may extend in the second direction along both sidewalls of the seed pattern to be opposite to each other.

The graphene layer may be formed using at least one of a chemical vapor deposition (CVD) process, an ion implantation process and an epitaxial growth process.

The seed layer may include at least one of nickel (Ni), cobalt (Co), copper (Cu), iron (Fe), platinum (Pt), gold (Au), aluminum (Al), chrome (Cr), magnesium (Mg), manganese (Mn), molybdenum (Mo), rhodium (Rh), silicon (Si), silicon carbide (SiC), tantalum (Ta), titanium (Ti), tungsten (W), uranium (U), vanadium (V) and zirconium (Zr).

The method may further include forming an insulation layer between the substrate and the seed layer. The insulation layer may include at least one of a silicon oxide layer, a silicon nitride layer and a silicon oxynitride layer.

In another exemplary embodiment, a method of forming a graphene device includes sequentially forming a seed layer and a first protection layer on a substrate, patterning the first protection layer and the seed layer to form a first protection pattern and a seed pattern having a first length in a first direction and a second length in a second direction perpendicular to the first direction, forming a graphene material on at least one of both sidewalls of the seed pattern, forming a second protection pattern covering the graphene material, and patterning the first protection pattern and the seed pattern to form first and second seed patterns separated from each other. The second length is greater than the first length.

Forming the first and second seed patterns may include defining a central portion of the first protection pattern and the seed pattern, and etching and removing the central portion of the first protection pattern and the seed pattern 12 using the second protection pattern as an etch mask to form an opening that divides the seed pattern into first and second seed patterns separated from each other.

Forming the second protection pattern may include forming a second protection layer on the substrate including the graphene material, and etching the second protection layer to expose the first protection pattern. The second protection pattern may be formed to cover the graphene material.

The method may further include removing the second protection pattern after formation of the first and second seed patterns.

The method may further include forming a gate insulation layer on the substrate including the first and second seed patterns, and forming a gate electrode on the gate insulation layer between the first and second seed patterns.

In yet another exemplary embodiment, a graphene device includes a first electrode and a second electrode disposed on a substrate to have a width in a first direction and to be spaced apart from each other in a second direction perpendicular to the first direction, a graphene layer disposed along at least one of both sidewalls of the first and second electrodes, and a protection pattern on the first and second electrodes. The graphene layer connects the first electrode to the second electrode.

In still another exemplary embodiment, a graphene device includes a first seed pattern and a second seed pattern disposed on a substrate to have a width in a first direction and to be spaced apart from each other in a second direction perpendicular to the first direction, a graphene layer disposed along at least one of both sidewalls of the first and second electrodes to connect the first seed pattern to the second pattern, a first protection pattern on the first and second seed patterns, a second protection pattern covering the graphene layer, a gate insulation layer covering the substrate, the first protection pattern, the second protection pattern, and a gate electrode on the gate insulation layer between the first and second seed patterns.

Each of the first and second seed patterns may include a plurality of sub-patterns. The first protection pattern may be disposed between the plurality of sub-patterns.

### BRIEF DESCRIPTION OF THE DRAWINGS

The above and other features and advantages of the disclosure will become more apparent in view of the attached drawings and accompanying detailed description.

FIGS. 1A to 3A are perspective views illustrating a method of forming a graphene material according to a first exemplary embodiment.

FIGS. 1B to 3B are vertical cross sectional views taken along lines I-I′ of FIGS. 1A to 3A, respectively.

FIGS. 4A to 7A are perspective views illustrating a graphene device according to a second exemplary embodiment and a method of forming the same.

FIGS. 4B to 7B are vertical cross sectional views taken along lines I-I′ of FIGS. 4A to 7A, respectively.

FIGS. 8A to 11A are perspective views illustrating a graphene device according to a third exemplary embodiment and a method of forming the same.

FIGS. 8B to 11B are vertical cross sectional views taken along lines I-I′ of FIGS. 8A to 11A, respectively.

FIG. 11C is vertical cross sectional views taken along lines II-II′ of FIG. 11A.

FIGS. 12A to 12C are vertical cross sectional views illustrating a method of forming a graphene material according to a fourth exemplary embodiment.

### DETAILED DESCRIPTION OF THE EMBODIMENTS

Exemplary embodiments are described hereinafter in detail with reference to the accompanying drawings. However, many different forms and embodiments are possible without deviating from the spirit and teachings of this disclosure and so the disclosure should not be construed as limited to the exemplary embodiments set forth herein. Rather, these exemplary embodiments are provided so that this disclosure will be thorough and complete, and will convey the scope of the disclosure to those skilled in the art. In the drawings, the sizes and relative sizes of layers and regions may be exaggerated for clarity. The same reference numerals or the same reference designators denote the same elements throughout the specification.

The terminologies used herein are for the purpose of describing particular embodiments only and are not intended to be limiting of the embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, steps, operations, elements, and/or components, but do not preclude the presence or addition of one or more other features, steps, operations, elements, components, and/or groups thereof

Exemplary embodiments of the inventive concepts are described herein with reference to cross-sectional illustrations and perspective views that are schematic illustrations of idealized embodiments (and intermediate structures) of exemplary embodiments. As such, variations from the shapes of the illustrations as a result, for example, of manufacturing techniques and/or tolerances, are to be expected. Thus, exemplary embodiments of the inventive concepts should not be construed as limited to the particular shapes of regions illustrated herein, but are to include deviations in shapes that result, for example, from manufacturing. For example, a region illustrated as a rectangle may have rounded or curved features. Thus, the regions illustrated in the figures are schematic in nature and their shapes are not intended to illustrate the actual shape of a region of a device and are not intended to limit the scope of exemplary embodiments.

As used herein the term “and/or” includes any and all combinations of one or more of the associated listed items.

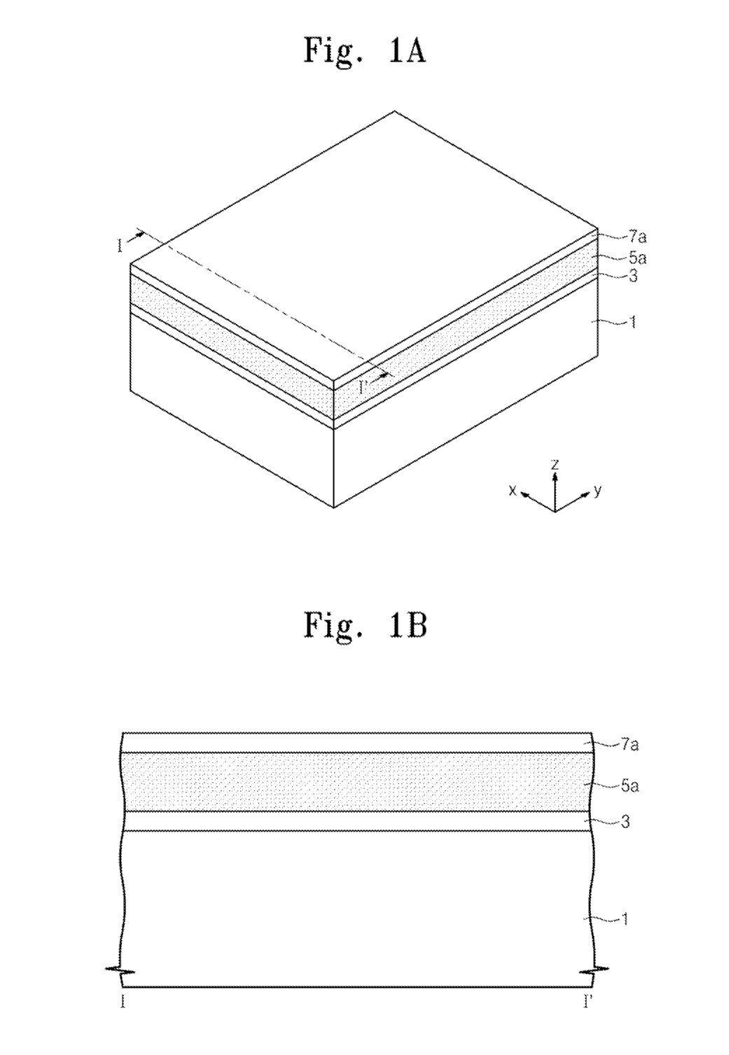

FIGS. lA to 3A are perspective views illustrating a method of forming a graphene material according to a first exemplary embodiment, and FIGS. 1B to 3B are vertical cross sectional views taken along lines I-I′ of FIGS. 1A to 3A, respectively.

Referring to FIGS. 1A and 1B, a seed layer 5a and a protection layer 7a may be formed on a substrate 1. The substrate 1 may include an insulation material or a semiconductor material. The insulation material may include at least one of a glass material and a plastic material, and the semiconductor material may include at least one of a silicon material, a silicon carbide (SiC) material and a germanium material.

An insulation layer 3 may be disposed between the substrate 1 and the seed layer 5A. The insulation layer 3 may include at least one of a silicon oxide layer, a silicon nitride layer and a silicon oxynitride layer.

The seed layer 5a may include transition metal. For example, the seed layer 5a may include at least one of nickel (Ni), cobalt (Co), copper (Cu), iron (Fe), platinum (Pt), gold (Au), aluminum (Al), chrome (Cr), magnesium (Mg), manganese (Mn), molybdenum (Mo), rhodium (Rh), silicon (Si), silicon carbide (SiC), tantalum (Ta), titanium (Ti), tungsten (W), uranium (U), vanadium (V) and zirconium (Zr). The seed layer 5a may be formed using a physical vapor deposition (PVD) process, a chemical vapor deposition (CVD) process, an atomic layer deposition (ALD) process and an evaporation process. The protection layer 7a may include a silicon oxide (SiO₂) layer, a silicon nitride (SiN) layer or a silicon oxynitride (SiON) layer.

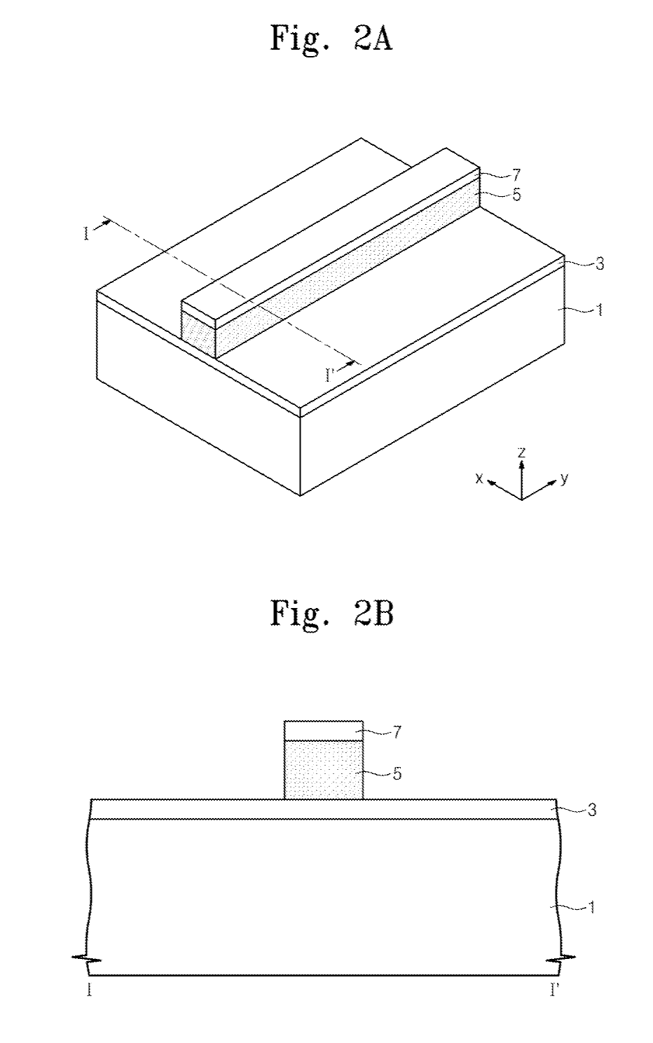

Referring to FIGS. 2A and 2B, the protection layer 7a and the seed layer 5a may be patterned to form a seed pattern 5 and a protection pattern 7. The seed pattern 5 and the protection pattern 7 may be formed by etching the protection layer 7a and the seed layer 5a using a wet etching process or a dry etching process. In an embodiment, the seed pattern 5 and the protection pattern 7 may be formed to have a first length in a first direction and to have a second length in a second direction perpendicular to the first direction. The second length may be greater than the first length. The first direction and the second direction may be parallel with an x-axis and a y-axis of FIG. 2A, respectively.

The etching process for patterning the protection layer 7a and the seed layer 5a may be performed using an acid material, a hydrofluoric (HF) material, a buffered oxide etchant (BOE), an iron chloride (FeCl₃) solution, a ferric nitrate (Fe(NO₃)₃) solution, a hydrogen chloride (HCl) solution or a combination thereof as an etchant. Alternatively, the protection layer 7a and the seed layer 5a may be etched using an ion beam etching process, an ion beam milling process or a sputter etching process.

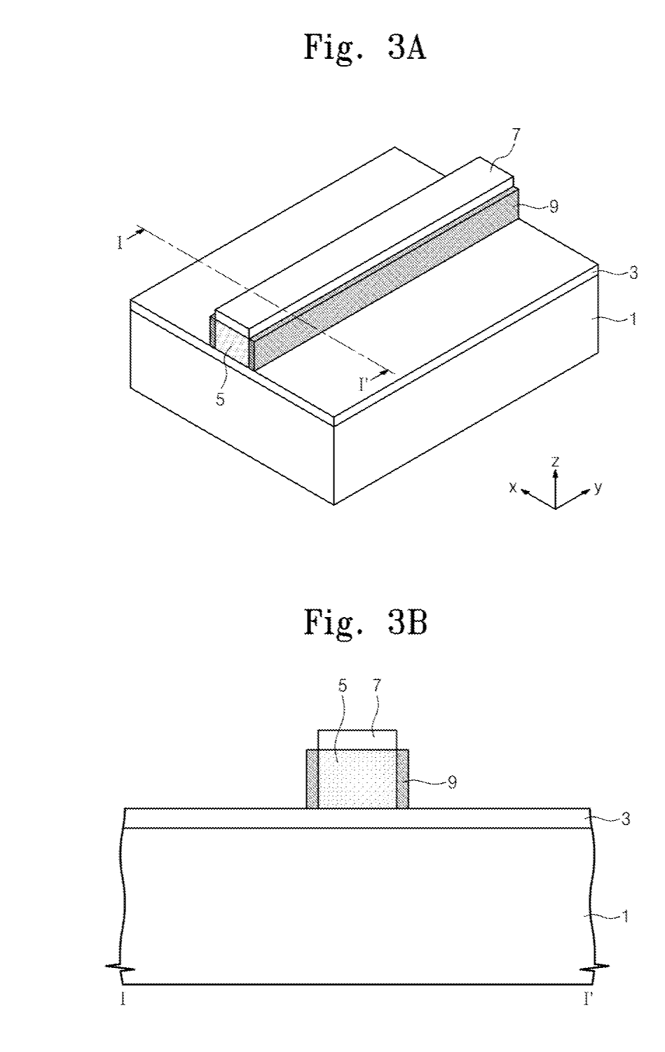

Referring to FIGS. 3A and 3B, a graphene layer 9 may be formed on at least one sidewall of the seed pattern 5. For example, the graphene layer 9 may be formed on both sidewalls of the seed pattern 5. Thus, the graphene layer 9 may extend in the second direction along both sidewalls of the seed pattern 5 and may include a pair of graphene patterns opposite to each other.

The graphene layer 9 may be formed using at least one of a chemical vapor deposition (CVD) process, an ion implantation process and an epitaxial growth process.

According to the exemplary embodiment described above, the graphene layer 9 may be formed along the sidewalls of the seed pattern 5. Thus, the graphene layer 9 may be formed on the substrate 1 having a large area. Further, a vertical width of the graphene layer 9 can be easily and accurately controlled by adjusting a deposition thickness of the seed layer 5a. Thus, a small and fine graphene layer 9 can be more readily formed. For example, it may be easy to form the graphene layer 9 having a width of about one or several nanometers. Further, the graphene layer 9 formed according to the exemplary embodiment can be directly applied to a device without use of any separation process and any transferring process of the graphene layer 9. Accordingly, a fabrication process of the graphene layer 9 may be simplified, and the graphene layer 9 may be formed on a large areal substrate.

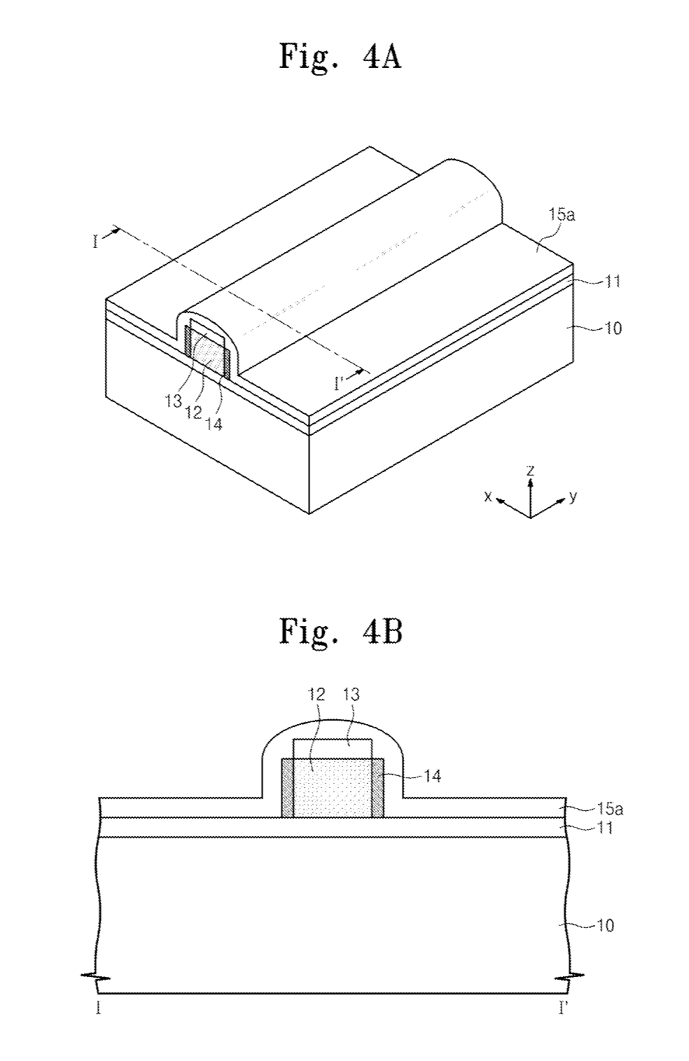

FIGS. 4A to 7A are perspective views illustrating a graphene device according to a second exemplary embodiment and a method of forming the same, and FIGS. 4B to 7B are vertical cross sectional views taken along lines I-I′ of FIGS. 4A to 7A, respectively.

Referring to FIGS. 4A and 4B, an insulation layer 11 may be formed on a substrate 10, and a seed layer and a protection layer may be sequentially formed on the insulation layer 11.

The protection layer and the seed layer may be patterned to form a seed pattern 12 and a first protection pattern 13. In an embodiment, the seed pattern 12 and the first protection pattern 13 may be formed to have a first length in a first direction and to have a second length in a second direction perpendicular to the first direction. The second length may be greater than the first length. The first direction and the second direction may be parallel with an x-axis and a y-axis of FIG. 4A, respectively. The seed pattern 12 and the first protection pattern 13 may be formed using the same etching processes as described in the first embodiment.

A graphene layer 14 may be formed on at least one sidewall of the seed pattern 12. The graphene layer 14 may be formed of a single layered material or a double-layered material. In an embodiment, the graphene layer 14 may be formed on both sidewalls of the seed pattern 12. Thus, the graphene layer 14 may extend in the second direction along both sidewalls of the seed pattern 12 and may include a pair of graphene patterns opposite to each other.

The graphene layer 14 may be formed using at least one of a chemical vapor deposition (CVD) process, an ion implantation process and an epitaxial growth process.

A second protection layer 15a may be formed to conformally cover the insulation layer 11, the seed pattern 12, the first protection pattern 13 and the graphene layer 14. The second protection layer 15a may be formed to protect the graphene layer 14.

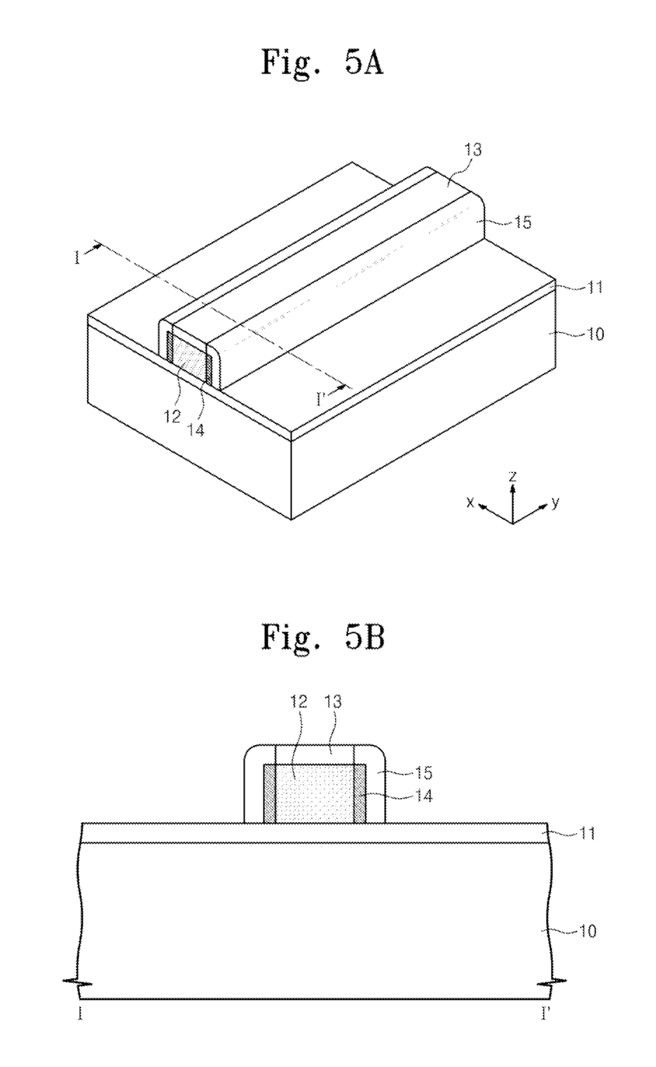

Referring to FIGS. 5A and 5B, the second protection layer 15a may be etched to form a second protection pattern 15 exposing the first protection pattern 13 and the insulation layer 11. As such, the second protection pattern 15 may be formed to cover the graphene layer 14. Alternatively, etching the second protection layer 15a may be omitted.

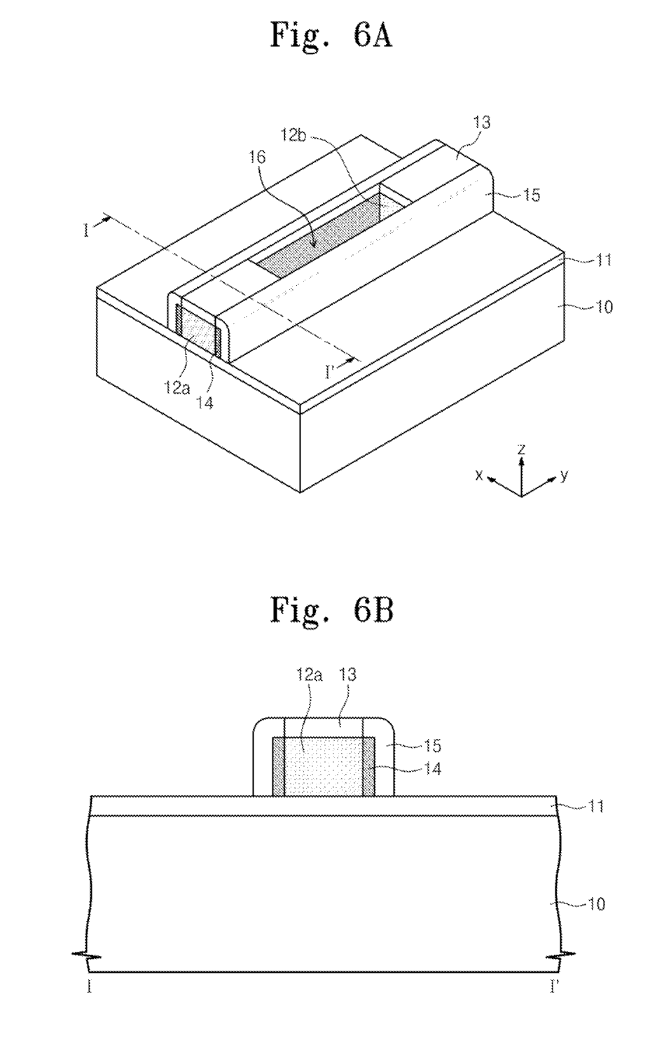

Referring to FIGS. 6A and 6B, the first protection pattern 13 and the seed pattern 12 may be patterned. Patterning the first protection pattern 13 and the seed pattern 12 may include removing a portion of the first protection pattern 13 and a portion of the seed pattern 12 using a photolithography process and an etching process.

In an embodiment, patterning the first protection pattern 13 and the seed pattern 12 may include defining a central portion 16 of the first protection pattern 13 and the seed pattern 12 extending in the second direction, and etching and removing the central portion 16 of the first protection pattern 13 and the seed pattern 12 using the second protection pattern 15 as an etch mask to divide the seed pattern 12 into first and second seed patterns 12a and 12b separated from each other.

Alternatively, patterning the first protection pattern 13 and the seed pattern 12 may be performed using at least one of a photolithography process, an electron-beam lithography process, a nano-imprint process, a dry etching process and a wet etching process.

In the event that etching the second protection layer 15a is omitted as described with reference to FIGS. 5A and 5B, the second protection layer 15a may be etched while the first protection pattern 13 and the seed pattern 12 are patterned.

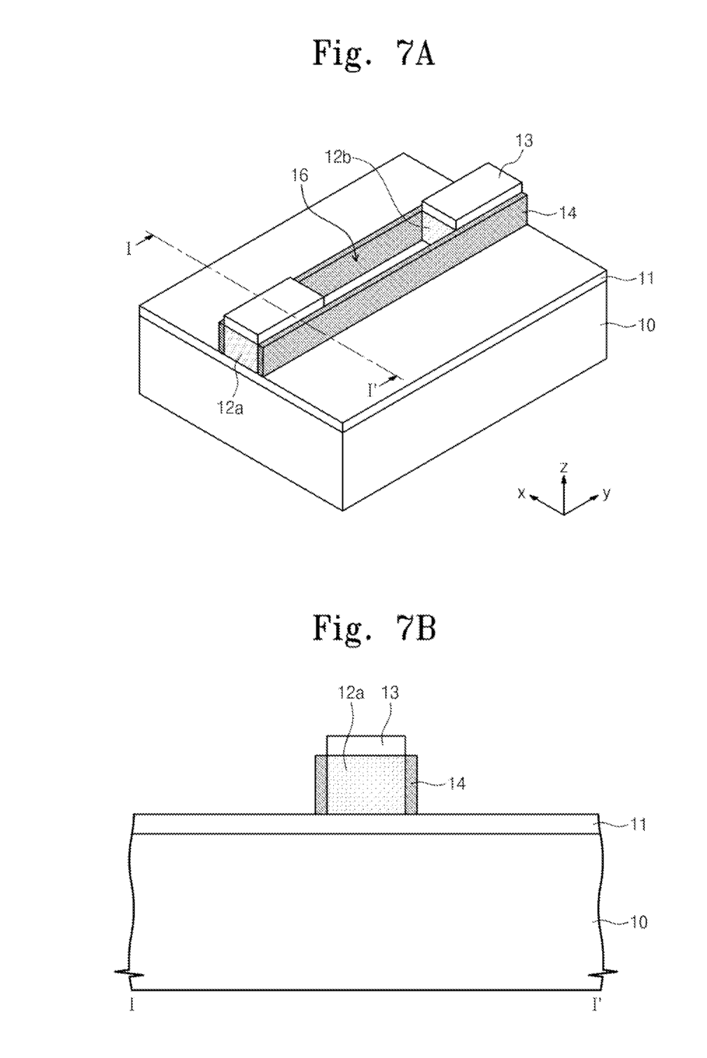

Referring to FIGS. 7A and 7B, the second protection pattern (15 of FIG. 6A) may be removed to expose the graphene layer 14. As a result, a grapheme device may be formed to include the separated first and second seed patterns 12a and 12b and the pair of graphene patterns 14 connecting the first seed pattern 12a to the second seed pattern 12b.

The grapheme device may be used as an electronic device, for example, a resistor, a conductor, a sensor or the like. For example, when the grapheme device is used as a sensor, an electrical characteristic of the grapheme device may vary according to a change in circumstance, for example, an environmental gas, a biological material or humidity.

In the event that the grapheme device is used as a sensor, the substrate 10 may be formed of a polymer material, for example, a polyimide material, a polyethylene terephthalate (PET) material or a polydimethylsiloxane (PDMS) material.

However, the material of the substrate 10 is not limited to the above listed materials. For example, the substrate 10 may be formed of any one of the materials described in the first embodiment.

The grapheme layer 14 may have a function that senses an actual variation of electrical resistance of a resistor. The first and second seed patterns 12a and 12b may act as electrodes. The electrodes may electrically connect the graphene layer 14 to an external circuit.

The graphene device according to the exemplary embodiment has a relatively large surface area. Thus, the graphene device may have an advantage of a high sensitivity. Further, as described above, the graphene layer 14 formed according to the exemplary embodiment can be directly applied to a device without use of any separation process and any transferring process of the graphene layer 14. Accordingly, a fabrication process of the graphene layer 14 may be simplified and damage to the graphene layer 14 can be prevented since the transferring process is omitted. Thus, a stable graphene device may be realized.

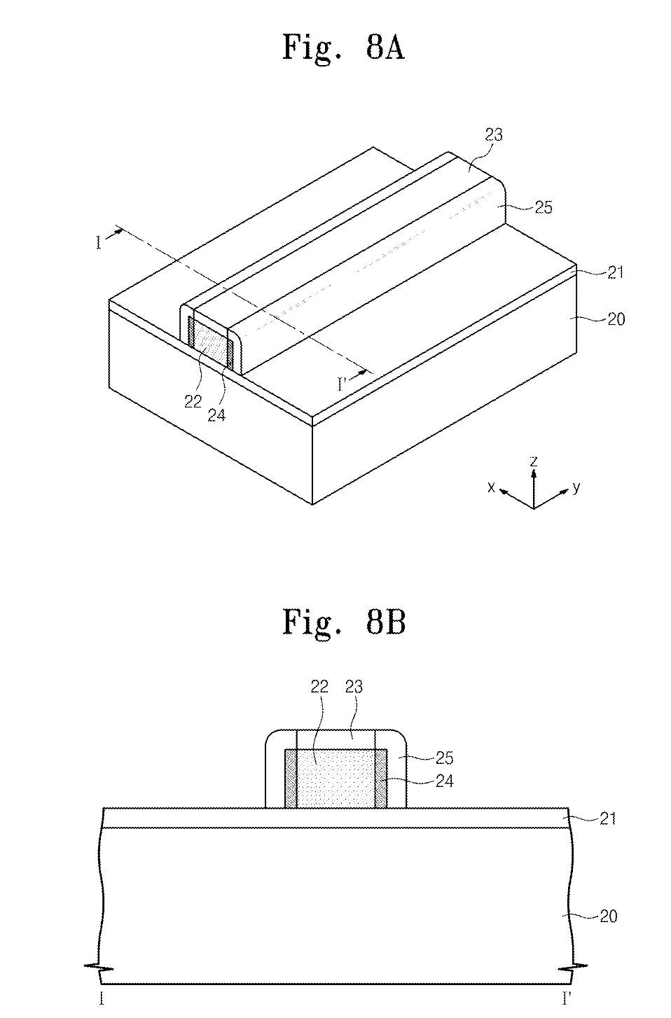

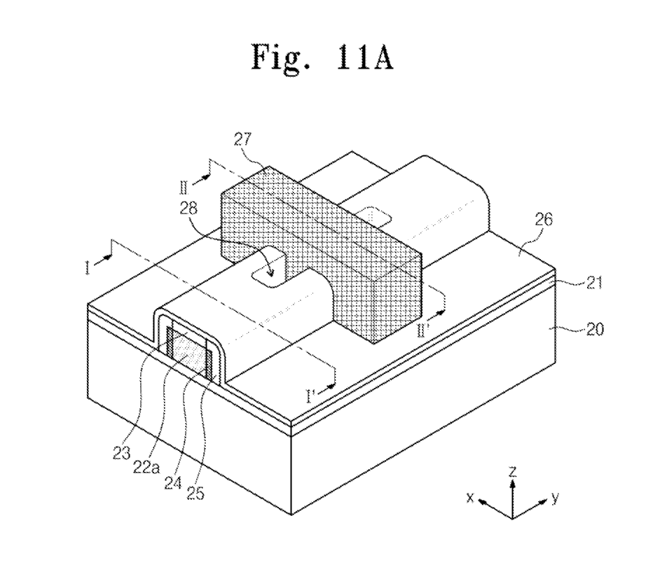

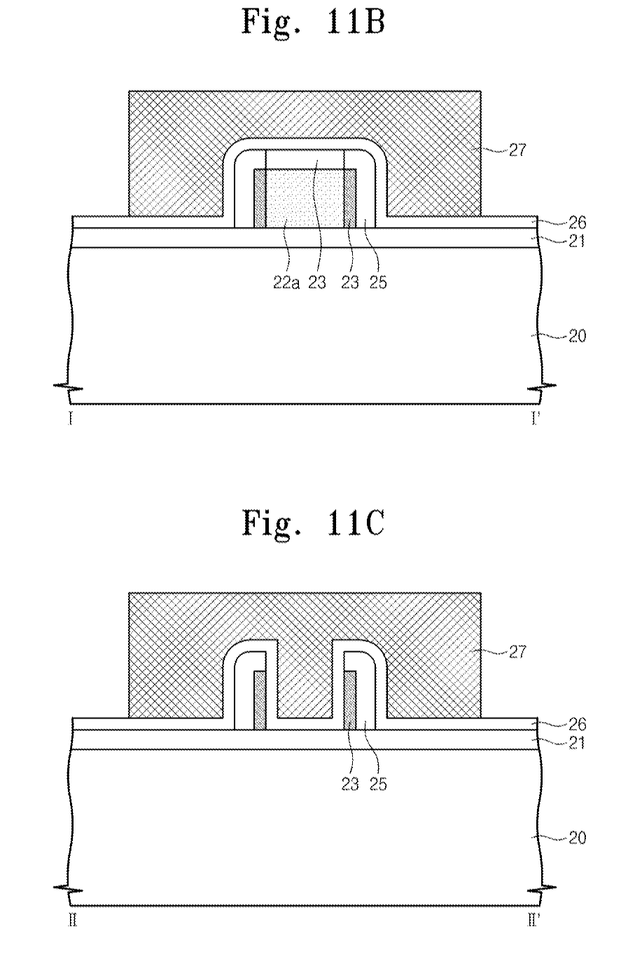

FIGS. 8A to 11A are perspective views illustrating a graphene device according to a third exemplary embodiment and a method of forming the same, FIGS. 8B to 11B are vertical cross sectional views taken along lines I-I′ of FIGS. 8A to 11A, respectively, and FIG. 11C is vertical cross sectional views taken along lines II-II′ of FIG. 11A.

The third exemplary embodiment may provide a transistor device employing the graphene layer formed according to one of the previous embodiments and a method of forming the same.

Referring to FIGS. 8A and 8B, as described in the previous embodiments, an insulation layer 21 may be formed on a substrate 20, and a seed layer and a first protection layer may be sequentially formed on the insulation layer 21. The first protection layer and the seed layer may be patterned to form a seed pattern 22 and a first protection pattern 23. In an embodiment, the seed pattern 22 and the first protection pattern 23 may be formed to have a first length in a first direction and to have a second length in a second direction perpendicular to the first direction. The second length may be greater than the first length. The first direction and the second direction may be parallel with an x-axis and a y-axis of FIG. 8A, respectively. The seed pattern 22 and the first protection pattern 23 may be formed using the same etching processes as described in the first and second embodiments.

A graphene layer 24 may be formed on at least one sidewall of the seed pattern 22. For example, the graphene layer 24 may be formed on both sidewalls of the seed pattern 22. Thus, the graphene layer 24 may extend in the second direction along both sidewalls of the seed pattern 22 and may include a pair of graphene patterns opposite to each other.

The graphene layer 14 may be formed using at least one of a chemical vapor deposition (CVD) process, an ion implantation process and an epitaxial growth process.

A second protection layer may be formed to conformally cover the insulation layer 21, the seed pattern 22, the first protection pattern 23 and the graphene layer 24. The second protection layer may be etched to form a second protection pattern 25 exposing the first protection pattern 23 and the insulation layer 21. As such, the second protection pattern 25 may be formed to cover the graphene layer 24.

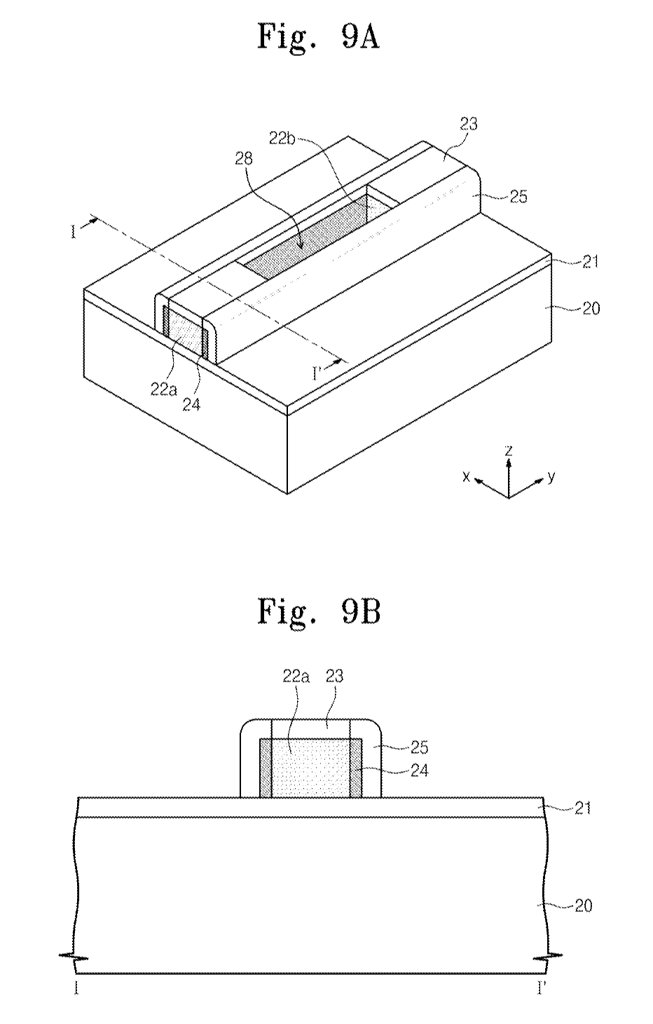

Referring to FIGS. 9A and 9B, the first protection pattern 23 and the seed pattern 22 may be patterned. Patterning the first protection pattern 23 and the seed pattern 22 may include defining a central portion of the first protection pattern 23 and the seed pattern (22 of FIG. 8A) extending in the second direction, and etching and removing the central portion of the first protection pattern 23 and the seed pattern 22 using the second protection pattern 25 as an etch mask to divide the seed pattern 22 into first and second seed patterns 22a and 22b separated from each other. Therefore, an opening 28 may be formed between the first and second seed patterns 22a and 22b.

The second protection pattern 25 may be removed to expose the grapheme layer 24 after formation of the first and second seed patterns 22a and 22b. Alternatively, removing the second protection pattern 25 may be omitted.

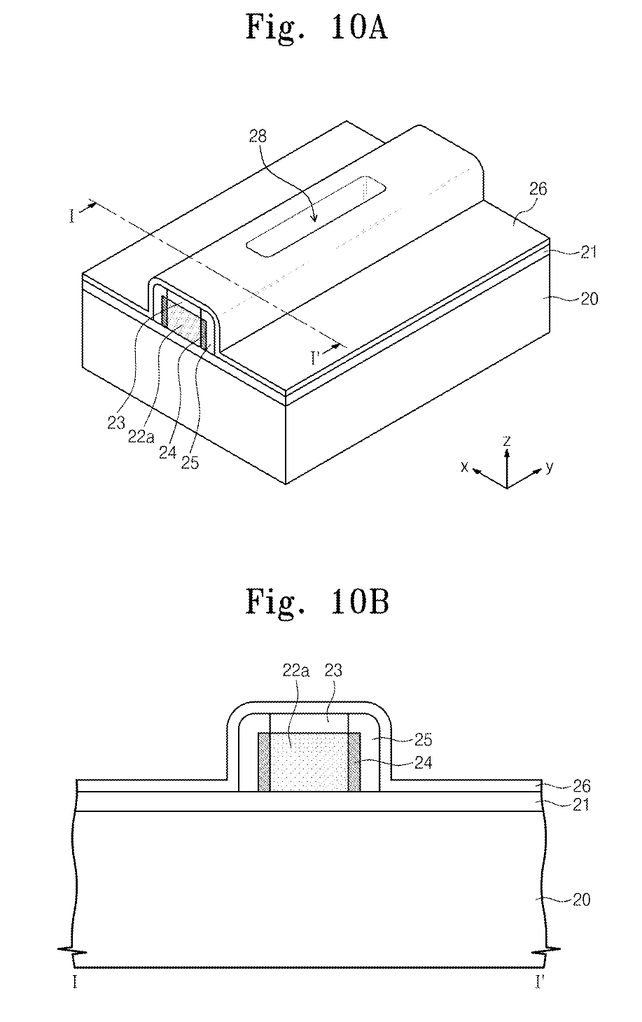

FIGS. 10A and 10B, a gate insulation layer 26 may be formed to conformally cover the substrate including the first and second seed patterns 22a and 22b. The gate insulation layer 26 may be formed to cover the insulation layer 21, the first protection pattern 23 and the second protection pattern 25. The gate insulation layer 26 may be formed of a silicon oxide layer, a silicon nitride layer, a silicon oxynitride layer or a high-k dielectric layer. The high-k dielectric layer may be a hafnium oxide (HfO₂) layer. The gate insulation layer 26 may be formed using an atomic layer deposition (ALD) process, a chemical vapor deposition (CVD) process or a spin coating process.

Referring to FIGS. 11A to 11C, a gate electrode 27 may be formed on the gate insulation layer 26 in the opening 28 between the first and second seed patterns 22a and 22b. The gate electrode 27 may extend in the first direction to cross over the opening 28. The gate electrode 27 may be formed of a metal material or a polysilicon material. The metal material may include a titanium (Ti) layer, an aluminum (Al) layer, a titanium nitride (TiN) layer, a platinum (Pt) layer or a tungsten (W) layer.

In an embodiment, forming the gate electrode 27 may include forming a polysilicon layer on the substrate, injecting impurities into the polysilicon layer, planarizing the doped polysilicon layer, forming a photoresist pattern on the planarized polysilicon layer, and etching the planarized polysilicon layer using the photoresist pattern as an etch mask. Subsequently, the photoresist pattern may be removed and source and drain regions may be formed to complete a transistor having a fin field effect transistor (FET) structure.

The first and second seed patterns 22a and 22b may act as a source electrode and a drain electrode, respectively.

The graphene layer 24 may act as a semiconductor layer. A vertical width of the graphene layer 24 can be easily and accurately controlled by adjusting a deposition thickness of the seed patterns 22a and 22b. For example, it may be easy to form the graphene layer 24 having a vertical width of about one or several nanometers. Further, the graphene layer 24 may have a band gap when the graphene layer 14 is doped with impurities. For example, the graphene layer 24 may be formed to have a width of about 10 nanometers or the less and to have a band gap.

The graphene layer 24 may have a high electron mobility as compared with typical semiconductor materials. Thus, the graphene layer 24 may be used in formation of a high reliable transistor.

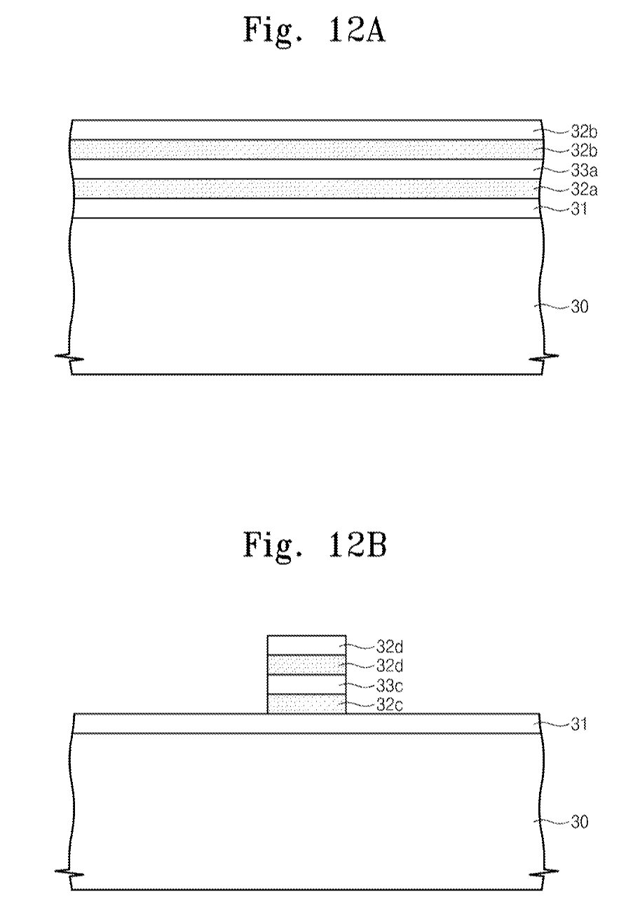

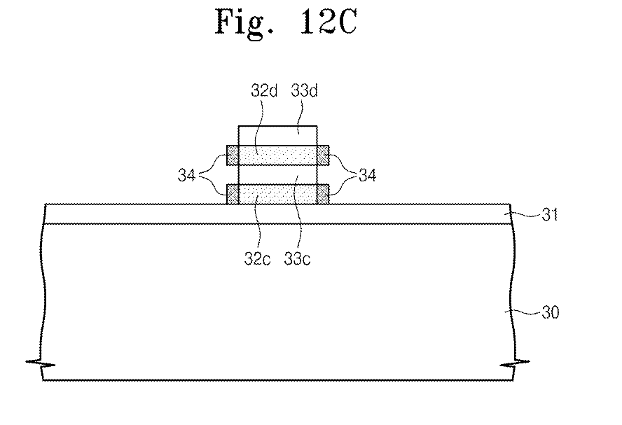

FIGS. 12A to 12C are vertical cross sectional views illustrating a method of forming a graphene material according to a fourth exemplary embodiment.

Referring to FIG. 12A, a first seed layer 32a, a first protection layer 33a, a second seed layer 32b and a second protection layer 33b may be sequentially formed on a substrate 30. An insulation layer 31 may be formed between the substrate 30 and the first seed layer 32a.

The substrate 30, the first and second seed layers 32a and 32b, the first and second protection layers 33a and 33b and the insulation layer 31 may be formed using the same manners as described in the previous embodiments.

Referring to FIG. 12B, the first and second seed layers 32a and 32b and the first and second protection layers 33a and 33b may be patterned to form first and second seed patterns 32c and 32d and first and second protection patterns 33c and 33d which are sequentially stacked.

The first and second seed patterns 32c and 32d and first and second protection patterns 33c and 33d may be formed by patterning the first and second seed layers 32a and 32b and the first and second protection layers 33a and 33b using an etching process. In an embodiment, the first and second seed patterns 32c and 32d and the first and second protection patterns 33c and 33d may be formed to have a first length in a first direction and to have a second length in a second direction perpendicular to the first direction. The second length may be greater than the first length. The first and second seed patterns 32c and 32d and the first and second protection patterns 33c and 33d may be formed using the same etching processes as described in the previous embodiments.

Referring to FIG. 12C, a graphene layer 34 may be formed on at least first sidewalls of the seed patterns 32c and 32d. For example, the graphene layer 34 may be formed on both sidewalls of each of the first and second seed patterns 32c and 32d. Thus, the graphene layer 34 may be formed of a double-layered material. The graphene layer 34 may extend in the second direction along both sidewalls of the seed patterns 32c and 32d and may include two pair of graphene patterns opposite to each other. The graphene layer 34 may be formed using at least one of a chemical vapor deposition (CVD) process, an ion implantation process and an epitaxial growth process.

The method of forming the graphene layer according to the present embodiment may be formed along both sidewalls of each of the first and second seed patterns 32c and 32d. Thus, the graphene layer 34 may be formed to have a double layered structure. The graphene layer 34 may have a semiconductor property. A vertical width of the graphene layer 34 may be determined by a thickness of each of the seed layers 32c and 32d. In addition, the graphene layer 34 may be formed to have a band gap.

Further, the graphene layer 34 may be directly applied to a device without use of a separation process and a transferring process. For example, the graphene layer 34 formed according to the present embodiment may be directly applied to the graphene devices disclosed in the second and third embodiments. Thus, since the transferring process is omitted, a fabrication process of the graphene layer 34 may be simplified and damage to the graphene layer 34 can be prevented. As a result, a stable graphene layer 34 may be formed.

According to the embodiments set forth above, a graphene layer may be formed along at least one of sidewalls of a seed pattern. Further, the graphene layer according to the embodiments can be directly applied to a device even without use of a separation process and a transferring process. Thus, a fabrication process of the graphene layer can be simplified and damage to the graphene layer can be prevented. As a result, a stable graphene layer may be formed on a substrate having a large area.

Moreover, a graphene device according to the exemplary embodiment may be applied to a transistor even without use of the transferring process, and a width of the graphene layer can be determined by a thickness of the seed pattern. In addition, the graphene layer can be formed to have a band gap. Since the graphene layer has a high electron mobility as compared with typical semiconductor materials, a high performance transistor may be realized using the graphene layer.

Furthermore, according to the exemplary embodiments, seed patterns remain to act as electrodes. Thus, any additional processes for forming the electrodes may not be required.

A graphene device according to the embodiment may be used as a resistor, a conductor, a sensor or the like. Since the graphene layer has an excellent electrical conductivity, a high performance and high reliable electronic device can be formed using the graphene layer.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A method of forming a graphene device, the method comprising:
sequentially forming a seed layer and a protection layer on a substrate;
patterning the protection layer and the seed layer to form a protection pattern and a seed pattern having a first length in a first direction and a second length in a second direction perpendicular to the first direction, the second length being greater than the first length; and
forming a graphene layer on at least one of both sidewalls of the seed pattern.

2. The method of claim 1, wherein forming the graphene layer includes forming a pair of graphene patterns on respective ones of both sidewalls of the seed pattern,
wherein the pair of graphene patterns extend in the second direction along both sidewalls of the seed pattern to be opposite to each other.

3. The method of claim 1, wherein the graphene layer is formed using at least one of a chemical vapor deposition (CVD) process, an ion implantation process and an epitaxial growth process.

4. The method of claim 1, wherein the seed layer includes at least one of nickel (Ni), cobalt (Co), copper (Cu), iron (Fe), platinum (Pt), gold (Au), aluminum (Al), chrome (Cr), magnesium (Mg), manganese (Mn), molybdenum (Mo), rhodium (Rh), silicon (Si), silicon carbide (SiC), tantalum (Ta), titanium (Ti), tungsten (W), uranium (U), vanadium (V) and zirconium (Zr).

5. The method of claim 1, further comprising forming an insulation layer between the substrate and the seed layer,
wherein the insulation layer includes at least one of a silicon oxide layer, a silicon nitride layer and a silicon oxynitride layer.

6. A method of forming a graphene device, the method comprising:
sequentially forming a seed layer and a first protection layer on a substrate;
patterning the first protection layer and the seed layer to form a first protection pattern and a seed pattern having a first length in a first direction and a second length in a second direction perpendicular to the first direction, the second length being greater than the first length;
forming a graphene material on at least one of both sidewalls of the seed pattern;
forming a second protection pattern covering the graphene material; and
patterning the first protection pattern and the seed pattern to form first and second seed patterns separated from each other.

7. The method of claim 6, wherein forming the first and second seed patterns includes:
defining a central portion of the first protection pattern and the seed pattern; and
etching and removing the central portion of the first protection pattern and the seed pattern 12 using the second protection pattern as an etch mask to form an opening that divides the seed pattern into first and second seed patterns separated from each other.

8. The method of claim 6, wherein forming the second protection pattern includes:
forming a second protection layer on the substrate including the graphene material; and
etching the second protection layer to expose the first protection pattern,
wherein the second protection pattern is formed to cover the graphene material.

9. The method of claim 6, further comprising removing the second protection pattern after formation of the first and second seed patterns.

10. The method of claim 6, further comprising:
forming a gate insulation layer on the substrate including the first and second seed patterns; and
forming a gate electrode on the gate insulation layer between the first and second seed patterns.

11. A graphene device comprising:
a first electrode and a second electrode disposed on a substrate to have a width in a first direction and to be spaced apart from each other in a second direction perpendicular to the first direction;
a graphene layer disposed along at least one of both sidewalls of the first and second electrodes; and
a protection pattern on the first and second electrodes,
wherein the graphene layer connects the first electrode to the second electrode.

12. A graphene device comprising:
a first seed pattern and a second seed pattern disposed on a substrate to have a width in a first direction and to be spaced apart from each other in a second direction perpendicular to the first direction;
a graphene layer disposed along at least one of both sidewalls of the first and second electrodes to connect the first seed pattern to the second pattern;
a first protection pattern on the first and second seed patterns;
a second protection pattern covering the graphene layer;
a gate insulation layer covering the substrate, the first protection pattern, the second protection pattern; and
a gate electrode on the gate insulation layer between the first and second seed patterns.

13. The graphene device of claim 12:
wherein each of the first and second seed patterns includes a plurality of sub-patterns; and
wherein the first protection pattern is disposed between the plurality of sub-patterns.
